(19) United States
(12) Patent Application Publication
(10) Pub. No.: US 2023/0209661 A1
(43) Pub. Date: Jun. 29, 2023

(54) METROLOGY DEVICE, SYSTEM AND METHOD

(71) Applicant: 4K-MEMS SÀRL, St Blaise (CH)

(72) Inventor: Matthias Imboden, St. Blaise (CH)

(21) Appl. No.: 17/793,367

(22) PCT Filed: Jan. 15, 2021
(86) PCT No.: PCT/EP2021/050879

§ 371 Date: Jul. 15, 2022

(30) Foreign Application Priority Data
Jan. 15, 2020 (CA) 3067973
Apr. 24, 2020 (CA) 3079443

(51) Int. Cl. H05B 3/14

(52) U.S. Cl. CPC H05B 3/143; H01L 22/10; H05B 2203/005

(57) ABSTRACT

A MEMS hotplate is used as a test substrate for characterizing a temperature-dependent fabrication process. According to a variant, an array of MEMS hotplates is used to provide multiple test substrates which can be simultaneously heated to different temperatures to provide multiple different temperature-dependent characterizations of the process.

### FIELD OF THE INVENTION

The invention relates to metrology or testing methods and devices for characterizing a temperature-dependent process performed on a surface or substrate.

### BACKGROUND OF THE INVENTION

Metrology techniques may be used to characterize processes in which the temperature of a substrate affects one or more parameters of a treatment process of the substrate. The examples given in this description relate to semiconductor or metallurgical fabrication processes performed on a substrate such as a silicon wafer. However, other processing techniques in other contexts may likewise require a substrate or surface to be at a particular temperature during processing. Such processing techniques may include coating, deposition, etching, abrasion, washing, annealing, sintering, polishing or other processes which are affected by the substrate temperature. Metrology techniques can be used to obtain characterization information which can be used to calibrate or adjust process parameters to obtain the desired process result on the substrate, in dependence on the substrate temperature. For example, it may be desired to identify an optimum temperature for depositing a particular characteristic (eg thickness or crystallographic structure) of a particular material deposited on a particular substrate, or to determine the characteristic(s) of the deposited material at each of various substrate temperatures.

### Prior Art

It is known to characterize a temperature-dependent silicon fabrication process by performing the process on one or more test wafers, with the test wafers at a different temperature for each test. The characterization may be performed with one test wafer, heated to a first temperature, then a second, then a third, etc, and with different regions of the wafer exposed to the fab process for each test. Or different wafers may be used for each test. In order to achieve a useful characterization of the process variation with temperature, many tests are needed, and many wafers, and the testing process takes a great deal of time. A fine-grained characterization would be out of the question.

By way of example, it is known in some thin-film fabrication methods to elevate the substrate (target) temperature in order to obtain a particular desired deposition rate and/or crystallographic structure of the deposited elements. Likewise, the substrate temperature may be varied to obtain a desired etch rate of a particular etching process, for example. In the growth of Neodymium Iron Boron (NeFeB) magnetic films, for example, the material may be deposited using sputtering with the substrate at a temperature (T_{D}) in the range 20° C. to 500° C. (https://doi.org/10.1063/1.2710771). Post deposition annealing up to 750° C. for multiple minutes enables crystallization and promotes grain growth. This annealing step is not only sensitive to the annealing temperature (T_{A}) and annealing time (t_{A}), but also the temperature ramp rate during heating (dT/dt_{A+}) and cooling (dT/dt_{A-}). This simple example includes five temperature-related parameters. If one were to scan the parameter space with just 4 values of each parameter, there would be 4⁵ = 1024 possible combinations. In practice, processes are characterized for a much smaller number of combinations on grounds of time and cost.

### BRIEF DESCRIPTION OF THE INVENTION

The present invention aims to overcome at least some of the disadvantages of the prior art. To this end, a metrology device according to the invention is described in claim 1, a metrology array according to the invention is described in claim 6 and characterization methods according to the invention are described in claims 9 and 10.

### DETAILED DESCRIPTION OF THE INVENTION

The invention will now be described in detail with reference to the attached drawings, in which:

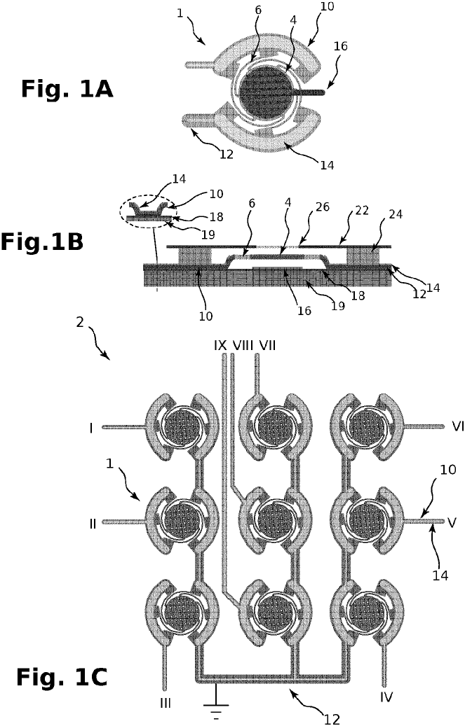

FIGS. 1A and 1B show plan and cross-sectional view of a MEMS hotplate element 1 suitable for carrying out the invention, including a central plate 4, tethers 6 and electrical leads 10, 12 which may be part-metallized 14. An electrode beneath the plate may be used for resonant actuation and detection.

FIG. 1C depicts a 3x3 array 2 of MEMS elements 1 such as those of FIG. 1.

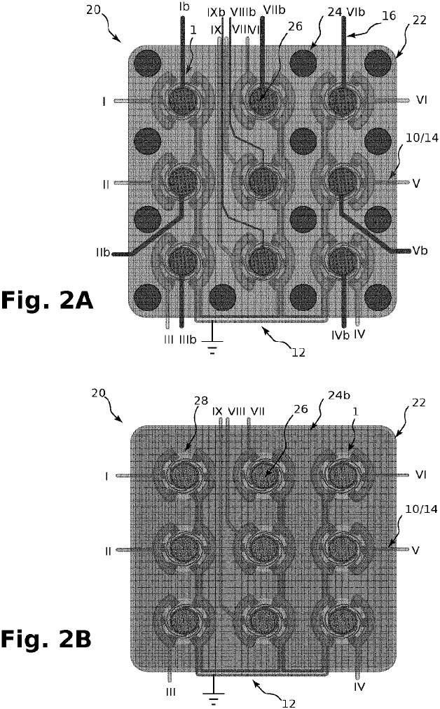

FIGS. 2A and 2B illustrate two variants of a shielded array 20. The shield 22 covers the electrical leads 10, 12, 14 as well as the heating elements of the device 1, but leaves the hot plate exposed.

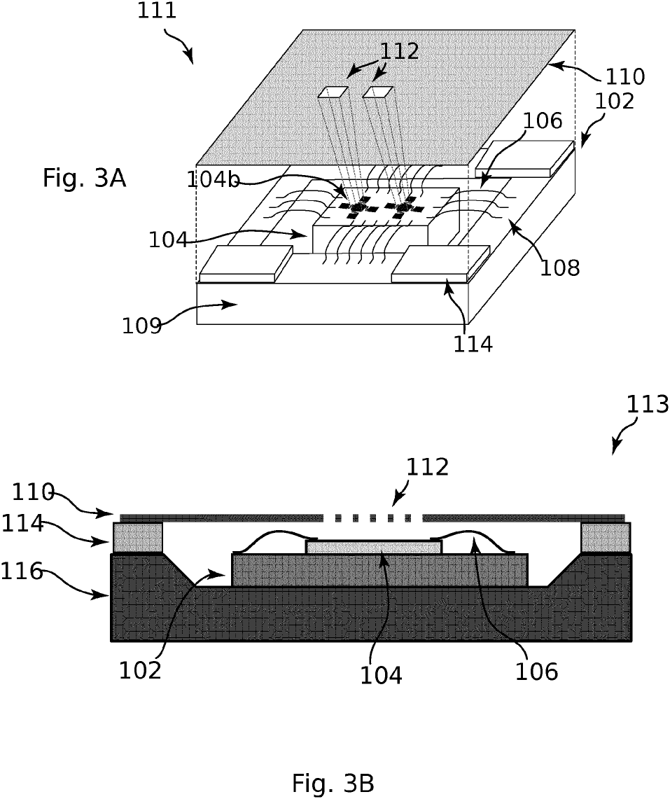

FIG. 3A illustrates the die 104 containing the MEMS hotplate array 2 packaged in a ceramic chip holder 102. A lid 110 with opening 112 shield the electrical connections 106.

FIG. 3B is a side view of the ceramic chip 102 mounted in a socket. In this implementation the lid is mounted on the socket.

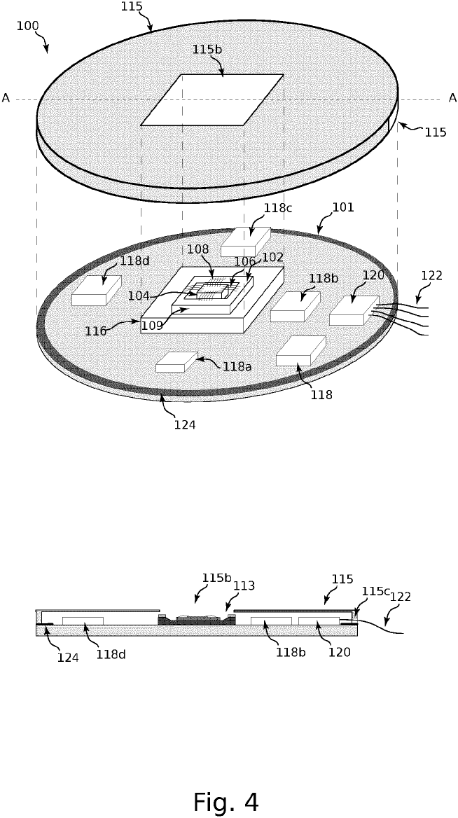

FIG. 4 is an example of the fabrication and analysis platform 100 with the socket, along with a temperature sensing element 118 and multiplexer 120 mounted on a PCB 102.

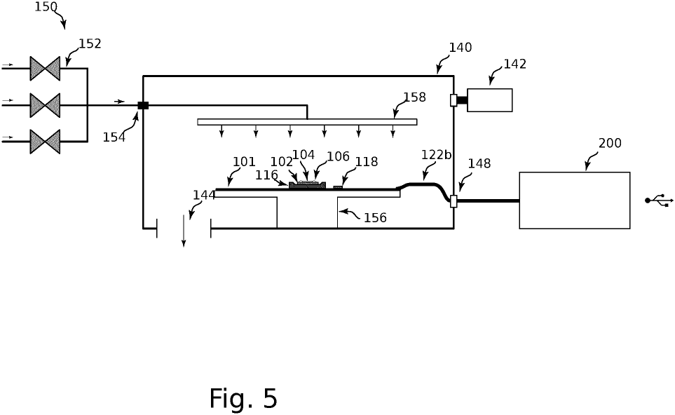

FIG. 5 is an example of a cold wall CVD system 150, the fabrication and analysis platform 100 and a thermal control unit 200.

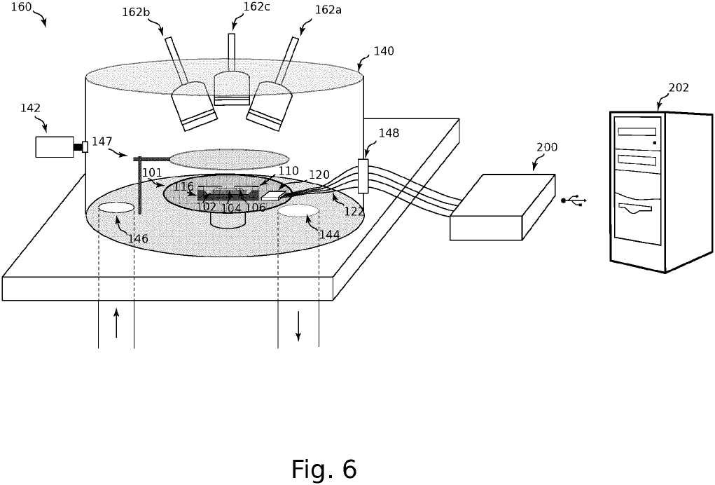

FIG. 6 is an example of a magnetron sputtering system 160 with the fabrication and analysis platform 100 and a temperature control unit 200a and a frequency control unit 200b which interface with a computer 202.

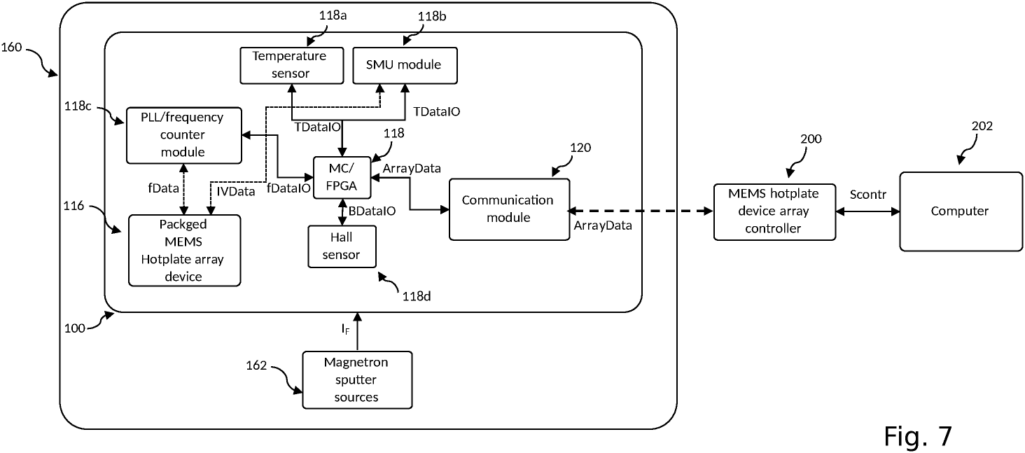

FIG. 7 is an example of the flow in information for sensing and controlling the temperatures of the MEMS hot plates used for magnetron sputtering deposition.

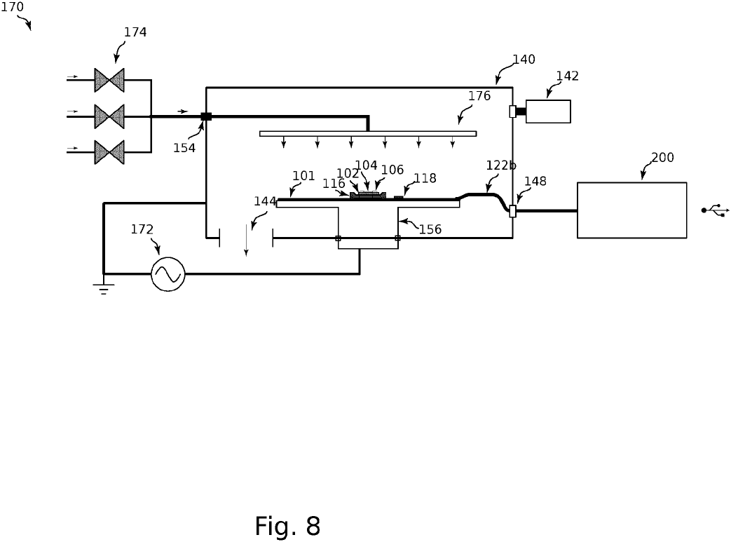

FIG. 8 is an example of a reactive ion etching unit 170 and a fabrication and analysis platform 100 along with a thermal control unit 200.

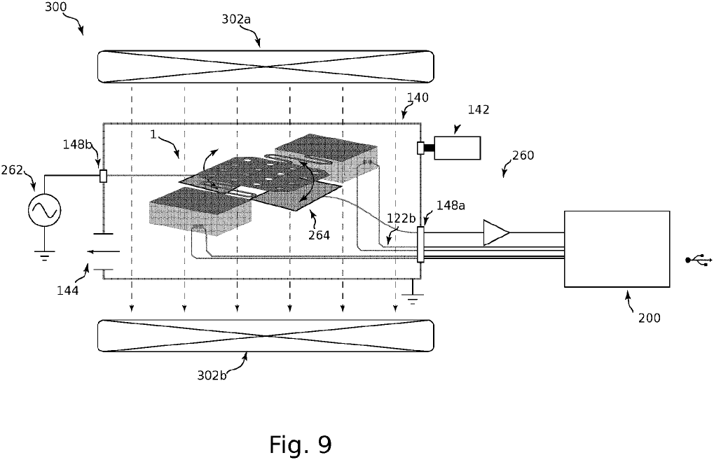

FIG. 9 is an example of a vacuum annealing chamber in a homogeneous magnetic field 300. A MEMS hot plate element is electrostatically actuated in a torsion mode which is sensed by a lock in amplifier 200c. Thermal treatment is controlled by a thermal control unit 200a.

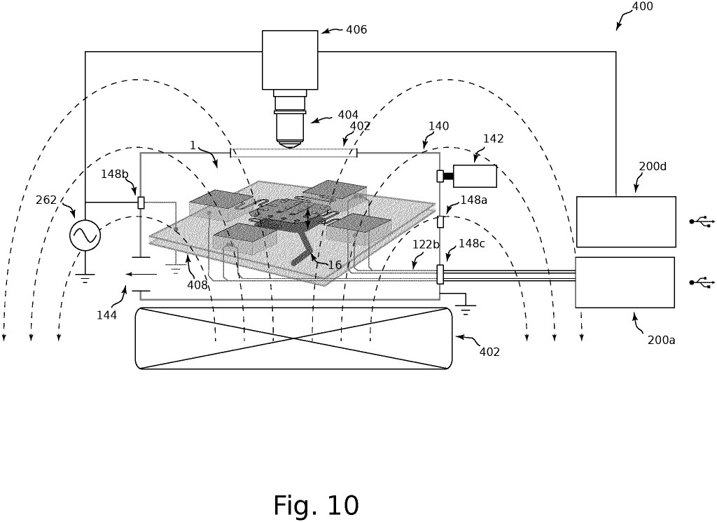

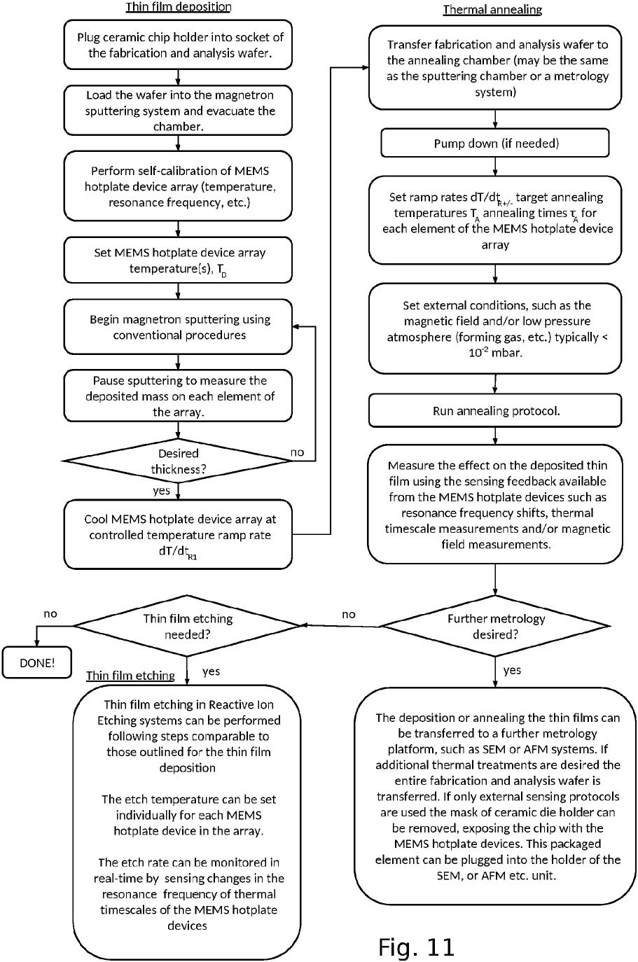

FIG. 10 is an example of a vacuum annealing chamber in an inhomogeneous magnetic field. The MEMS hotplate is actuated in a vertical translation mode by a piezoelectric shaker 408 and sensed using a Doppler vibrometer measurement system consisting of the laser and optics 406 and control unit 200d. Thermal treatment is controlled using the thermal control unit 200a.

It should be noted that the figures are provided merely as an aid to understanding the principles underlying the invention, and should not be taken as limiting the scope of protection sought. Where the same reference numbers are used in different figures, these are intended to indicate similar or equivalent features. It should not be assumed, however, that the use of different reference numbers is intended to indicate any particular degree of difference between the features to which they refer.

This invention proposes to use arrays of MEMS hot plates as deposition substrates (targets). Such an array may consist of individual elements, arrays of 2×2 elements or 10×10 or more. As each element can be set to a well-defined temperature a total of 100 deposition temperatures could be tested simultaneously. Post deposition etching or thermal treatments could again be performed simultaneously and individualized for each plate. Consequently, finding the optimal thermal conditions for deposition, annealing, end etching could be accomplished 100× faster. The method described is applicable for deposition, annealing, and etching processes which occur at vacuum, at pressures typically, but not limited to, below 2×10⁻² mbar. Such deposition methods may include, but are not limited to, Low pressure Cold Wall Chemical Vapor Deposition (CVD), Plasma Enhanced CVD, Sputtering, Reactive Ion Sputtering, Magnetron Sputtering, Atomic Layer Deposition (ALD), and Physical Vapor Deposition (PVD) (including thermal and e-beam evaporation). The etching may take place in a reactive ion etching system, where an RF voltage creates a plasma which results in an an-isotropic etch of the substrate. Annealing may occur in vacuum or rarified gas (low pressure). As often processes are temperature dependent, the MEMS hotplate elements enable the efficient optimization of deposition, etching and annealing parameters.

In the context of semiconductor fabrication, the invention may MEMS hot plates as a tool for thin-film deposition, reactive etching, and thermal treatment methods. The MEMS hot plates enable high level of control of the temperature of the deposition substrate, deposition mass and post deposition thermal treatment. Lastly, the MEMS can also enable intrinsic characterization of the deposited thin-film. The ability to create an array of MEMS hotplate elements allows the user scan the thermal landscape with high precision. The ability to test deposition, etching, and post deposition thermal treatment parameters in parallel, along with in-situ feedback, improves the efficiency in optimizing thin-film growth protocols.

The heating elements create an array of deposition targets.

Each target can be held at a unique, well defined temperature during deposition (T_{D}) or etching (T_{E}).

The temperature can be monitored using the resistance of the heating elements

The temperate can be changed (dT/dt₊) in millisecond time scales (tᵣₐₘₚ) (which is interesting for multi-layer depositions were each layer can be deposited at a unique substrate temperature).

By adding an electrode below the heating elements, the elements can be resonated. The change in resonance frequency (f₀) is a direct measure of the mass of the deposited material. (The deposition rate may be temperature dependent).

After deposition, the heating elements can be used as annealing elements. In this case the temperature (T_{A}), temperate ramp rates (dT/dt_{A}) and annealing temperature time (t_{A}) can be set individually for each heating element.

The resonance can be used to monitor the annealing effects. For example: if a magnet is being annealed then and external homogeneous field will induce a torque on the magnets. This restoring torque will result in a frequency change of a torsion mode. Therefore, the frequency shift in the torsion mode due to an applied external field can be used as a measure of the magnetization of the deposited film.

The modular system would also allow the chip containing the thermal array to be mounted in a specially developed socked in characterization systems. This includes, but is not limited to, material characterization systems such as optical microscopy (with vacuum chambers), Scanning Electron Microscopes (SEM), Vacuum Atomic Force Microscopes (AFM), Vacuum X-ray diffractometers (XRD), and Raman Spectrometers, etc. The array enables the characterization of materials deposited on the hotplates over a wide thermal parameter space, with respects to surface morphology, crystallography, and chemical bond vibrations which may alter as a function of temperature or during thermal annealing processes.

A small die, such as 2.5×2.5 mm² may contain, for example, an individual hot plate with a diameter or up to 1×1 mm², or for example, an array of 2×2 hot palate with a diameter of 0.5 mm each or for example, an array of 3×3 with a diameter of 0.2 mm each, etc. up to an array, for example of 10×10 with a diameter of 0.05 mm each.

To summarize: These arrays can be used to optimize growth, post growth annealing conditions and etching, in particular related to thermal treatment. Implemented as resonators they can be used for real-time feedback of deposition rates, etch rates, and serve to track and quantify changes in material properties due to annealing treatments.

The device described may advantageously be made of a single material. One could also add a stack or a conformal coating to ensure chemical compatibility. For example, it is known that a conformal ALD deposited layer of Al₂O₃ will chemically separate incompatible materials such as silicon and gold, at elevated temperatures.

The MEMS hotplate device 1 depicted in FIGS. 1A and B includes a central plate element 4 which is mechanically suspended by heating elements 6. The heating elements 6 a conducting and by applying a voltage across them a current will be induced which will heat the central plate. The number of heating elements must be even, and is typically 4, but often 6 or 8. There can also be only two heater elements, or as many as 16 or even 32.

The central plate can be heated using the heating elements to 500 deg C or over 1000 deg C or over 2000 deg C up to 4000 deg C if the heating elements and the central plate are made of refractory ceramic materials such as, but not limited to HfC, TaC, or TaHfC. The heating elements suspend the central plate element above the substrate such that it is not touching the substrate. The void between the plate and the substrate is typically 2-20 microns deep, but may be larger. The heating elements are such that they can expand, flex and bend as they are heated. This flexure releases the thermal stresses that occur as the heating elements and the central plate are heated to high temperatures. The structures are made of a single material. The material is curved to the substrate at the anchors. This has two functions; 1 it physically attaches the heaters to the substrate and 2 it creates an overhand so that deposited material does not short out the devices. This is depicted in the inset of FIG. 1B

The central plate element is typically 50-100 microns in diameter, but depending on the application smaller diameters, down to 10 microns or smaller can are interesting when larger arrays are desired (described below), or the thermal time constants are needed to be very small, such as well below 1 millisecond. Correspondingly, much larger central plate elements may be of interested, 200 microns, or even 400 microns or even 600 microns in diameter. The MEMS hotplate devices with larger diameter central plates will tend to have larger number of heating elements, they will have a slower thermal response time which defines the time needed to heat or cool the MEMS hotplate devices, and will typically not be able to heat to as high a temperature due to the thermal radiation cooling effects. For these reasons the larger plates will have a maximum temperature in the range of 1000 K or up to 2000 K depending on geometry, material and number of heating elements. To minimize this cooling effect, materials with low emission coefficient are best suited for larger MEMS hotplate device with larger plates.

The hotplate device includes electrical leads, 10 one of which may be ground 12. To improve the efficiency these leads can be metallized 14, which reduced the electrical resistance in the leads. Typical resistance of each heating element is 1000 Ohms, but can be lower or higher. Typical resistance of the metallized leads is below 1 Ohm. Beneath the central plate 4 and the heating elements 6 there is a void. Beneath the void there is an electrode 16, which may be segmented. This electrode make is possible to mechanically actuate and/or sense the corresponding displacement of the central plate 4. Such sensing can be capacitive sensing, or optical sensing or piezoresistive sensing. The actuation can be thermal, capacitive (electrostatic) or piezo-electric using a shaker platform. Such actuation is typically alternating, resulting a vibrational motion of the pate. Ideally this is on resonance or close to resonance. For the devices presented the resonant frequency is typically between 10 kHz and 1 MHz. For larger plates this can be as low as 100 Hz, or for smaller plates this can be as high as 10 MHz or even 100 MHz. Depending on the actuation method the resonant mode can be out of plane, in plane or a torsional mode.

The MEMS hotplate device 1 can be placed in an array as illustrated in FIG. 1C. FIG. 1C shows an example of an array 20 of 3×3 hot plate devices. Each device can be individually addressed. In the example given the devices have 6 heater elements each. In the example given there the array is a 3×3 array of MEMS hotplate device. One could also conceive a smaller array of 1×1 or 2×2 MEMS hotplate elements, alternatively a significantly larger array can also be constructed, of 4×4, 5×5 etc. even up to 10×10 elements. These arrays built on dies 2.5×2.5 mm², but smaller or larger dies can be considered typically ranging from 1×1 mm² to 10×10 mm² or larger. In FIG. 1C the elements of the array are innumerate in roman numerals, in this example from I to IX to uniquely identify the nine electrical leads needed to heat the plates to nine unique temperatures.

The MEMS hotplate devices 1 are used to heat the central plate 4. The heat is applied by passing a current though the heater devices 6. The current is driven by applying a voltage bias, typically between 0-5 volts between the leads 10 and 12. These leads are metallized 14 to reduce electrical losses between the power source and the heating elements. The voltage bias drives a current thought the device, proportional to the device resistance. The resistance is typically a function of temperature and may be linear or not. The hotplates are calibrated and a look-up table can be used to determine their temperature by comparing the hot pate element electrical resistance change with respect to a reference temperature. For materials such as metal, or highly doped semiconductors, as is the case with highly doped silicon with phosphor, the resistance increases with temperature. This temperature dependence means that monitoring the resistance, for example by measuring the current resulting from the applied voltage bias, can be used to determine the temperature of the hotplate of a calibrated device. The increasing resistance with rising temperature also helps stabilize the MEMS hotplate device as the heating becomes self-limiting. (If the heating elements are made of a material with a decreasing resistance with increasing temperature then it is preferred to apply a current bias instead of a voltage bias.) The voltage bias can be constant, ramped or modulated. A square wave, or individual square pulse can be applied. By monitoring the resulting current one can calculate the thermal time constant t_{T}. For known material properties and MEMS hotplate device geometries one can use this to calculate the thermal load. If the thermal properties are known and the thermal load is measured then this information can be used to determine the mass of the material deposited or etched from the central hotplate. Hence, the thermal control and feedback module can used to 1) set a target temperature, b) set a thermal annealing profile and c) used to measure thermal time constants from which material properties and/or deposition and etch rates can be deduced. As outlined in the next paragraph the thermal control and feedback module can also d) measure piezoresistive changes of the resistance of the heating elements and e) thermo-mechanically actuate the device.

The MEMS hotplate devices include an electrode 16 placed below the central plate. This electrode can be used to capacitively sense the distance between the central plate and the electrode. Applying a voltage to electrode 16 will result in the electrostatic attraction of the plate. Resonant or pulsed signals can be used to actuate mechanical modes in the MEMS hotplate device. These modes can be sensed using the same capacitive electrode, optically, by reflecting a laser off the surface of the central hotplate, and/or piezoresistivity, by measuring changes in the resistance of the heating arms, which are also the flexural elements of said resonator. Changes in the resonance frequency, f, of the modes (at a fixed temperature) can be used to measure changes in mass, m:

$$\frac{Δ f}{f} = \frac{Δ m}{m}$$

The changes in mass, measured though changes in the thermal response time or preferably by changes in resonance frequency (equivalent to the mechanical response time) can be used to determine deposition or etch rates, an important feedback feature enabled by the MEMS hotplate devices. Of both mechanical and thermal timescales are precisely measured, then this information can be used to calculate both the mass (mechanical mass) and the thermal load (thermal mass) of the deposited material. Like this it is possible to determine a deposition rate or etch rate for each element of the MEMS hotplate device array independently and in-situ of the thin film deposition or etching system.

To protect the electrical leads from the deposition material, or the reactive ion etching, they may be covered. Such masking is illustrated in FIGS. 2A and 2B. In one implementation (FIG. 2A) a masking plate 22 is mounted on spacers 24 that raise the masking plate above the MEMS hotplate device array. In FIG. 2B the masking plate 22 is grown on a planarized spacer 24. The material of the masking plate is chosen so that it does not interfere with the thin-film growth process or is not significantly etched by the reactive ion etching process. This may be, but is not limited to a hard metal such as tungsten or Iron, or alternatively silicon, or silicon carbide, or a ceramic material. The spacer may be made of an easily etched material such as silicon dioxide, or a polymer such as SU8, such that the etch process during fabrication fully releases the MEMS hotplate device, resulting in a suspended, free standing structure with an appropriate undercut.

Depending on the deposition and etch processes performed, it may also be possible to only mask the heater elements 6, as is illustrated in FIG. 1B and in the example given in the prior art. Here, the electrical readout leads are curved up at the edges, illustrated in FIG. 1B. This prevents an an-isotropically deposited conductor from shorting out the structures. For the deposition of very thin, insulating materials, no such shielding is required. An example, but not limited to, is the atomic layer deposition of Al₂O₃.

The MEMS hotplate device array is built on a chip, typically 1×1-10×10 mm². This chip 104 is mounded in a chip holder, typically a ceramic chip holder 102 as illustrated in FIG. 3A (perspective view) and FIG. 3B cross sectional view. Electrical contacts are made from the leads, 10 and 12 to the chip holder pads 108 with wire bonds or ball bonds 106, typically made of aluminum or gold. A shield 110 with opening 112 is mounted over the die and electrical connectors on spacers 114. This shield protects the die and electrical leads from coating by the deposition materials or the reactive ion etching. In FIG. 3B illustrates the chip holder 102 mounted in a socket 116. In this implementation the socket includes the spacer 114 and shield 110 with the opening 112 which exposes the MEMS hotplate devices to the flux of deposition material or the reactive ions. The contacts 106 of the chip holder interface with contacts on the socket.

FIG. 4 illustrates the integration of the socket 116 which includes the chip holder 102 and mounted die 104, together with a thermometer 118 and multiplexer 120 on a disc, such as a PCB 101. This fabrication and analysis platform 100 replaces the wafer which would typically be used in such deposition and etching processes. The electrical control signals, for sensing and actuation of the MEMS heater devices, are transmitted to and from the fabrication and analysis platform through electrical wires 122. In an alternative implementation these wires could be replaced by wireless communication protocols such as Bluetooth. While in this example the PCB 101 includes thermometry feedback 118 and a multiplexer 120, other implementations may include additional control and logic elements, including, but not limited to, hall sensors for magnetic field sensing, integrated PID loops for temperature control of the MEMS hotplate devices and phase locked loop (PLL) circuits for monitoring changes in the resonance frequency of the MEMS hotplate devices. In its simplest implementation the fabrication and analysis platform 100 only includes interfacing with the communication and control wires 122. While the hotplate devices may each independently be set to an individual temperature, the temperature measured by the thermometer 118 defines the base temperature (or minimum temperature) and is also used for calibration of the MEMS hotplate devices.

FIGS. 5, 6, and 7 exemplify deposition systems in conjunction with the MEMS hotplate devices along with a schematic illustration of the communication and control (FIG. 7). The examples provided include Cold Wall CVD and Magnetron sputtering thin-film deposition systems.

FIG. 5 illustrates a Cold Wall Low Pressure Chemical Vapor Deposition (CWLPCVD) system 150, characterized by a gas manifold system 152 which feeds the precursor and carrier gases into the vacuum chamber 140 through a gas vacuum feedthrough 154. The gas mixture is released into the vacuum chamber through the cold showerhead 158. The gas is directed towards the fabrication and analysis platform with the array of MEMS hotplate devices which is mounted on a platform 156. The gas mixture reaching the hot central hotplate of the MEMS hotplate devices will react and deposit the desired material on the central hotplate. Surplus gas is evacuated from the vacuum chamber through the vacuum pump port 144. The vacuum is monitored by the pressure sensor 142. In order for the of MEMS hotplate devices to function as designed the pressure in the vacuum chamber must be low, below 10⁻¹ mbar for temperatures up to 300 deg C, below 10⁻² mbar for temperatures up to 800 deg C and ideally below 10⁻³ mbar for temperature exceeding 800 deg C. MEMS hotplate materials and specific geometries and heater element configurations will influence such parameters. For example, smaller central hotplates 4, with a diameter for example of less than 50 microns, coupled to a larger number of heating elements 6, can sustain higher temperatures at higher pressures. For temperatures above 1000 deg C thermal radiation becomes a significant or even dominant cooling mechanism which in turns limits the size of the hotplate and imposes additional constraints on the number of heating elements needed to obtain a desired setpoint temperature even as the vacuum pressure drops well below 10⁻³ mbar.

In the CWLPCVD realization the fabrication and analysis platform includes a thermometer 118 for temperature monitoring and calibration but no multiplexing element. In this case each element is addressed directly using the commination electrodes 122b which are fed out of the vacuum chamber through electrical vacuum feedthrough port 148 to a control and communication module 200. This module may be stand alone or interface with a computer, tablet or smart phone, for example using a USB connection or wireless communication protocols.

The second example, illustrated in FIG. 6, is that of a magnetron sputtering system 160. The system includes a vacuum chamber 140, vacuum pumping port 144 and vacuum gauge 142 as well as a blanking shutter 147 and gas inlet port 146. The blanking shutter prevents deposition on the fabrication and analysis platform until a predetermined time, such as when all set temperatures of the MEMS heater devices have reached their desired setpoint. The gas inlet port can be used to feed inter gasses such as argon into the chamber, needed for sputtering, as well as chemically active gasses such as, but not limited to, hydrogen, nitrogen or oxygen for reactive sputtering. The magnetron sputtering system also includes cathode targets 162a-c which may be DC or AC targets depending on the desired deposition materials. Typically, SC cathodes are uses for conductors such as metals, and AC cathodes for insulators and semiconductors such as SiO₂ and Si. Reactive sputtering modes can be used for the deposition of Oxides, Nitrides and Carbides. The anode is formed by the platform 156 and on the fabrication and analysis platform 100. The same pressure-temperature considerations as discussed for the CWLPCVD implementation also apply for the magnetron sputtering system, as well as the other deposition and reactive ion etching, and thermal annealing and characterization systems.

In this example of the implementation the on the fabrication and analysis platform includes a multiplexing element 120 which can address a large array and transfer signals between the fabrication and analysis platform (such as temperature information) and the MEMS heating devices (such as the set voltage and measured device resistance) and the control and communication modules 200a and 200b. In this example the wire bundle 122 and feedthrough 148 may contain fewer cables as the information is digital, compared to the direct electrical access to the devices described previously. There are two independent control and communication modules. Control and communication module 200a is used to set and monitor the temperature profile of the MEMS hotplate device array, were the control and communication module 200b is used for monitoring the resonance frequency, of the mechanical displacement of the MEMS hotplate device array. As discussed above, this information can be used to determine deposition rates and additional material properties. In either case the modules can be stand alone or interface with a computer 202, tablet or cell phone using USB or Bluetooth communication.

FIG. 7 illustrates the flow of information. This example is specific to the magnetron sputtering setup which generates a flux of deposition material I_{F}, but is equivalent to the other deposition, etching or annealing and characterization systems. A computer 202 is used to set a temperature profile and sense the mechanical displacement of a MEMS hotplate device array. The information (temperature control Tcont and frequency control fcont) is sent to the corresponding communication and control modules 200a and 200b. These modules interpret the commands and relay the information into the vacuum chamber of the deposition system (TData and fData) to the multiplexer 120 on the fabrication and analysis platform 100. The multiplexer addresses directly the array and applied the drive signals Min and records the output signals Mout from the MEMS hotplate device array. The multiplexer also interfaces with additional sensors on the fabrication and analysis platform such as the temperature sensor 118 used for calibration. The recorded information is sent back to the computer via the temperature communication and control module 200a and the control unit and the resonance communication and control module 200b. The communication and control module can set the desired temperature profile of the MEMS hotplate device array and interpret measurements, such as changes in resonance frequency or thermal timescales as described above. Consequently, both etch rates and material properties can be deduced from the measurements performed by the communication and control units during the deposition process.

The provided thin-film deposition examples are illustrative and not limiting. Using the same methodology, the system described can also be included in other, standardized thin-film deposition systems, such as, but not limited to, Physical Vapor Deposition System (in which case the fabrication and analysis platform 100 is inverted, facing down, as the material flux would typically come from below), Atomic Layer Deposition, Sputtering, and Reactive Ion Sputtering.

Thin-film etching can be performed by reactive ion etching (RIE). Such a setup is illustrated in FIG. 8. The RIE system 170 includes a vacuum chamber 140 consisting of a vacuum gauge 142 and pumping port 144 as well as a gas vacuum feedthrough line 154 interfacing with a gas flow manifold. Such a system enables the flow of reactive and inert gases such as, but not limited to O₂, NO, N₂O, Ar, H₂, HBr, SF₆, CF₄, NF₃, CHF₃, C₄F₈, Cl₂, BCl₃, CCl₄, NH₃. The gas forms a plasma between the electrodes formed by the chamber walls and gas inlet 176, held a ground) and the target which consists of the platform 156 and the fabrication and analysis platform 100 set to an oscillating potential at radio frequencies, typically at 13.56 MHz. The temperature of the etch is set by the array of MEMS hotplate devices through the communication and control module 200. In this example no multiplexing is implemented and the communication and control module 200 interfaces directly with the MEMS hotplate device array. The communication and control module can set the desired temperature profile of the MEMS hotplate device array and interpret measurements, such as changes in resonance frequency or thermal timescales as described above. Consequently, both etch rates and material properties can be deduced from the measurements performed by the communication and control units during the etching process. The reduced mass will also result in a reduced thermal load, hence the etch rate could also be monitored by measuring the thermal time constant of the devices. In such an implementation no frequency feedback would be required. The temperature communication and control module would simply apply a square wave voltage bias and measure the corresponding current. This information is passed on to a computer, smartphone or tablet using, for example, a USB or Bluetooth interface. The same pressure-temperature considerations as discussed for the CWLPCVD implementation also apply for the RIE system, as well as the other deposition and thermal annealing and characterization systems.

FIGS. 9 and 10 illustrate two examples of post deposition annealing and characterization. On booth cases the device is placed in a vacuum chamber 140 with corresponding pressure sensing 142, vacuum port 144, and electrical feedthrough 148(a-c). In these examples the chamber is placed in a magnetic homogeneous magnetic field (Homogeneous Field Setup 300 with corresponding electromagnetic coils 302a and 302b) (FIG. 9) and inhomogeneous magnetic field (Inhomogeneous Field Setup 400 with corresponding electromagnetic coil 402) (FIG. 10). The purpose if this implementation is to study a magnetic material deposited on the MEMS hotplate devices, for example, but no limited to Neodymium Iron Boron (NeFeB). Varying the annealing temperature, annealing time and corresponding temperature ramp rates will result in changes in the crystal structure and domain grown of the deposited thin-film. The external field can magnetize the thin-film, also at precisely chosen temperatures. Subsequent frequency measurements can be used to infer certain material properties such as magnetization strength of the annealed and magnetized thin-film.

In the Homogeneous Field Setup depicted in FIG. 9 the magnetic field is homogeneous and will result in a restoring torque on a torsional resonator if the magnet is aligned in parallel to the external field. This restoring force will increase the resonance frequency of the device. The mechanical resonance frequency is determined capacitively using the electrodes 264 and read-out by the frequency control unity 200c, where in this case the transimpedance amplifier 260 is external, but could be integrated in 200c as well. In the absence of a magnetic field the resonance frequency can be measured as a baseline. In the presence of the homogeneous magnetic field the resonance frequency will increase as the magnetization interacts with the external magnetic field to generate a restoring force. The strength of magnetization can be inferred from the frequency dependence with regards to the applied field.

Inhomogeneous Field Setup depicted in FIG. 10, the mems device is placed in a diverging magnetic field, created for example, by a single coil 402. A ferromagnetic material, or a magnetized material, for example, will be attracted (or possibly repulsed) in the presence of the magnetic field. This displacement can be measured capacitively using the electrode 16 and/or an interferometric setup illustrated by the optical window 402 used to shine a laser off the central plate, along with optics 404 and laser scanning mirrors 406. In a dynamic implementation 406 is a Doppler vibrometer. The mechanical actuation is implemented using a piezoelectric shaker 408 driven by a ac voltage generator 262. Typical frequencies would range from 10-100 kHz, but may be as low as 100 Hz or as high as 10 MHz, or more. The communication and control unit 200a is sued to set the annealing temperature profile, where the communication and control unit 200d is used to control and measure the mechanical displacement of the MEMS hotplate device.

The examples illustrated the annealing of a magnetic thin-film in the presence of a magnetic field. The same setup can be used in other material characterizations systems, with the requirement that the MEMS hotplate device array is in vacuum. Examples include, but are not limited to SEMs, vacuum AFMs, vacuum XRD, and vacuum Raman Spectrometers, along with optical microscopes interfacing with a vacuum chamber though an optical window. In particular the SEM is a simple interface as the SEM chambers tend to be large and are held under high vacuum. The fabrication and analysis platform 100 can be mounted on the SEM stage. Most SEM chambers also have electrical feedthrough options, so interfacing with a thermal control and feedback module is possible. This makes it possible to observe changes in surface morphology with regards to the annealing protocol chosen. AFM systems mounted in vacuum chambers can perform surface topology analysis to much higher degree of precision. One advantage of the MEMS hotplate devices is the high rate at which they heat or cool. Hence, one can heat, hold, cool and image at relatively high rates (thermal cycling timescales can be as low as 1-10 ms) to observe changes over time and thermal profiles, while all measurements are performed at ambient temperatures. This is particularly important for AFM measurements which include direct contact between the AFM tip and the sample, requiring that there not be a larger thermal gradient which can prohibit useful measurements. The high temperatures which can be applied by the MEMS hotplate devices may not only anneal the deposited structures, such as changing the crystal structure or domains, but can also induce phase changes (melting or evaporating) and chemical reactions in multi-material depositions. Hence, the platform can be used to measure thermal and chemical properties of the deposited materials.

What is claimed is:

1-12. (canceled)

13. A metrology array, said metrology array configured to simultaneously perform a plurality of temperature-dependent processes, said metrology array comprising,
a plurality of metrology MEMS devices, with each said metrology MEMS device comprised of,
a respective substrate plate, said respective substrate plate configured for being heated to a respective predetermined temperature and each substrate plate suspended by a plurality of first support arms, and arranged for being subjected to a respective process, each respective substrate plate and/or its arms are formed of a ceramic or silicon material,
each of the support arms for each respective substrate plate is connected ohmically to its plate and configured to be electrically heated by passing electric current through the support arms to their respective plates,
each of the support arms is connected thermally to its plate and configured such that each plate is heatable to a respective predetermined temperature by the heat generated in its arms,
wherein the arms of the plurality of metrology MEMS devices are connected to their respective plates and are adapted to heat their respective plates independently to different temperatures.

14. The metrology array of claim 13 wherein the plurality of MEMS devices are formed as a single component.

15. The metrology array according to claim 13 wherein the arms and plates of each of the MEMS devices are respectively formed of a single contiguous material.

16. The metrology array according to claim 13 wherein said MEMS devices each have a diameter between 0.01 mm and 2 mm.

17. The metrology device according to claim 16 wherein said MEMS devices each have a diameter between 0.05 and 1 mm.

18. A method of using an array of metrology devices to determine a temperature sensitive parameter of a process simultaneously at different temperatures, said method comprising:
constructing said array of MEMS metrology devices wherein,
each MEMS metrology device of said array of MEMS metrology devices having a substrate plate, and further wherein the substrate plate of each MEMS metrology device are configured to be heated independently to preselected temperatures,
each substrate plate having a plurality support arms to suspend each of the substrate plates,
each support arm being connected ohmically to its respective substrate plate, with each support arm configured to be heated by passing electric current through the support arm to its plate,
each of the plurality of support arms being thermally connected to its plate and configured such that the plate is heatable to its preselected temperature via heat from its support arms,
passing current through the arms of the MEMS devices to raise the temperatures of the plates to said different preselected temperatures
performing said process while the substrate plates are at their respective preselected temperatures.

19. The method according to claim 18 wherein each MEMS metrology device of said array of MEMS metrology devices has a diameter between 0.01 mm and 2 mm.

20. The method according to claim 19 wherein the MEMS metrology devices of said array of MEMS metrology devices are formed as a single component at the constructing said array of MEMS metrology devices step.

21. The method according to claim 20 wherein the MEMS metrology devices of said array of MEMS metrology devices are formed as a single contiguous material at the constructing said array of MEMS metrology devices step.
